(19) United States
(12) Patent Application Publication
(10) Pub. No.: US 2014/0000955 A1
(43) Pub. Date: Jan. 2, 2014

(54) Conformal Coating Capable of Scavenging a Corrosive Agent

(71) Applicants: Dylan J. Boday, Tucson, AZ (US); Joseph Kuczynski, Rochester, MN (US); Jason T. Wertz, Wappinger Falls, NY (US); Jing Zhang, Poughkeepsie, NY (US)

(72) Inventors: Dylan J. Boday, Tucson, AZ (US); Joseph Kuczynski, Rochester, MN (US); Jason T. Wertz, Wappinger Falls, NY (US); Jing Zhang, Poughkeepsie, NY (US)

(73) Assignee: INTERNATIONAL BUSINESS MACHINES CORPORATION, Armonk, NY (US)

(21) Appl. No.: 13/535,518

(22) Filed: Jun. 28, 2012

(51) Int. Cl. H01L 23/28; H01C 17/00; B05D 5/00

(52) U.S. Cl. 174/521; 427/58; 427/101

(57) ABSTRACT

A corrosion-resistant apparatus may contain an electronic component having a metal covered by a conformal coating. The conformal coating may contain polymer chains with unsaturated groups capable of scavenging a corrosive agent. The conformal coating may contain an accelerator or activator so that the unsaturated groups more readily scavenge the corrosive agent. In an embodiment, the conformal coating is a silicone coating with unsaturated pendant groups which scavenge a sulfur containing agent.

### TECHNICAL FIELD

This disclosure relates to anti-corrosive coatings. More particularly, this invention relates to conformal coatings for electronic components that protect the components from corrosion in environments with corrosive agents.

### BACKGROUND

Corrosion is a problem in industrial environments. Due to the sensitive nature of electronics, small amounts of corrosion may have great operational consequences. Often, corrosion can be prevented by controlling the source of corrosion in an environment. However, the source may be beyond the control of an entity. In those cases, an entity may instead protect its equipment from corrosion through coatings and other localized protection mechanisms. One such uncontrollable source of corrosion is the air. A large component of airborne corrosion is sulfur-based, which may attack and corrode sensitive electrical equipment.

### SUMMARY

In one embodiment, a corrosion-resistant apparatus includes an electronic component containing a metal, and a polymer coating covering the electronic component, the polymer coating having unsaturated groups.

In another embodiment, a method for coating an electronic component includes providing an electronic component containing a metal, and covering the electronic component with a polymer coating, the polymer coating having unsaturated groups.

### BRIEF DESCRIPTION OF THE DRAWINGS

The drawings included in the present application are incorporated into, and form part of, the specification. They illustrate an embodiment of the present invention and, along with the description, serve to explain the principles of the invention. The drawings are only illustrative of a typical embodiment of the invention and do not limit the invention.

FIG. 1 is a cross-sectional representation of a thick film resistor containing silver, which may be subject to sulfur corrosion.

FIG. 2 is a representation of sulfur structures that may be part of a silicone network of sulfur-vulcanized silicone formed by sulfur containing agents, according to embodiments of the invention.

### DETAILED DESCRIPTION OF THE DRAWINGS

This disclosure relates to a polymer coating used to protect an underlying electronic apparatus from sulfur corrosion. The polymer coating may both integrate sulfur into the coating and act as a barrier against further corrosion by sulfur and other corrosive agents. The polymer coating may contain polymer chains with unsaturated groups and an accelerator.

Sulfur may be present in an atmosphere in various corrosive forms including elemental sulfur (S₈), hydrogen sulfide (H₂S), and sulfur oxides (SO₂, SO₃). Sources for the sulfur containing agents include various industrial processes, fossil fuel combustion, dimethylsulfide (DMS) production from plankton and other biological sources, and volcanic eruptions.

Conformal coatings have been used to help prevent corrosion of electronic components from sulfur and other gases and particulates by acting as a physical barrier to the corrosive agents. However, these coatings do not necessarily protect the underlying electronic components from sulfur corrosion. Sulfur is soluble and permeable in many polymeric materials, and may absorb into and diffuse through a polymer coating. In many instances, the polymer coating may make sulfur corrosion worse. Absorption of sulfur into the coating may increase the concentration of sulfur to many times that found in the surrounding atmosphere. Additionally, moisture can get trapped beneath the polymer coating, speeding up corrosion.

Sulfur corrosion may affect many metals in electronic components, but it is especially a problem with components that use corrosion-resistant metals like silver and copper as conductors, such as film and gate resistors. Silver and copper are excellent conductors of electricity and are generally corrosion resistant, often serving as conducting pathways. The tendency of sulfur to attack these metals, which may be accelerated by galvanic forces acting on the metals when used in metallic junctions, can cause the electronic components to fail.

For example, in the field of resistors, silver may form a conducting path between a resistor element and solder attaching the resistor to a printed circuit board. Sulfur compounds in the atmosphere may react with silver to produce silver sulfide. As the corrosion progresses, formation of silver sulfide increases the resistance of the resistor, until all the silver in a local part of the resistor is gone and the resistor ceases to pass current. This phenomenon has been seen in resistors with and without conformal coatings.

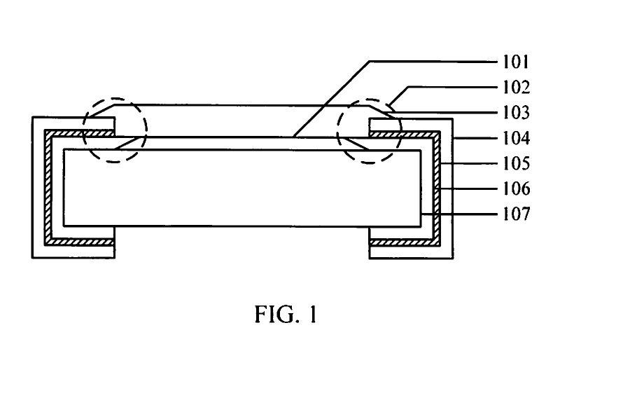

FIG. 1 is a cross-sectional representation of a coated thick film resistor containing silver, where silver sulfide corrosion may occur. The resistor element 101 is applied to a ceramic base 107 and coated with a protective conformal coating 103. A silver layer 106 provides a conductive medium to complete the circuit. This silver layer 106 is supported by a layer of nickel 105. The resistor is attached to a circuit board with solder 104, which may also contain silver. Silver sulfide corrosion is most likely to occur near the silver and coating interfaces 102.

### Material Mechanism

In embodiments of the invention, a conformal coating may remove sulfur permeating through the coating and form a protective layer through vulcanization. Vulcanization is a chemical process involving cross-linking polymer chains through a cross-linking agent, such as sulfur or peroxide. Vulcanization may be assisted through the addition of accelerators and activators, which act as catalysts for the vulcanization process.

According to principles of the invention, the conformal coating may protect an underlying electronic component in two ways. Firstly, in order for sulfur to corrode an electronic component having a conformal coating, the sulfur must permeate the conformal coating, absorbing into and diffusing through the coating. If the conformal coating contains polymer chains with unsaturated groups, the unsaturated groups may scavenge the sulfur, using the sulfur to crosslink the unsaturated functionality of the polymer. This scavenging action may be done with or without accelerators and activators. Secondly, the conformal coating with crosslinked polymer chains may act as a protective layer for the electronic component. After the silicone coating is vulcanized, the sulfur and silicone crosslinks, chains, and cyclics form a network that helps to prevent further permeation of corrosive agents through the silicone coating.

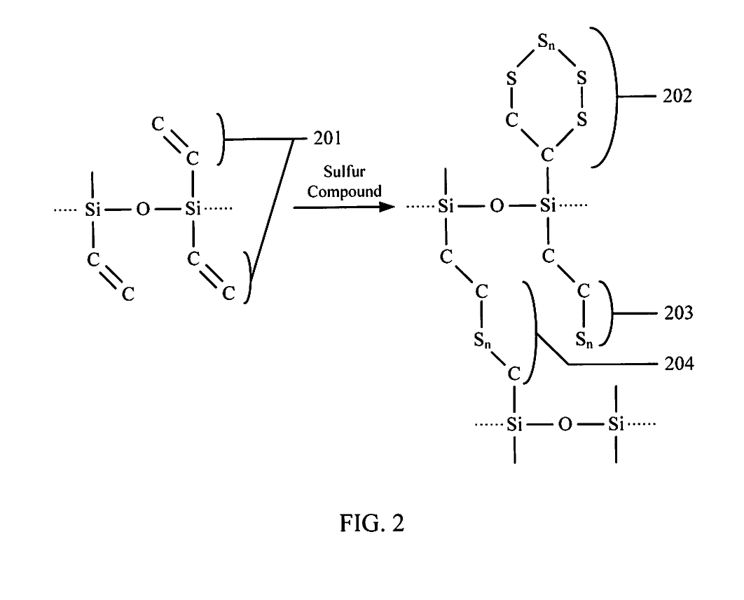

FIG. 2 is a representation of the sulfur orientations that may exist in a vulcanized polymer network, in this example silicone. Unsaturated pendant groups 201 are available for scavenging sulfur, and may do so through the vulcanization process. Sulfur may form a cyclic sulfide 202. Sulfur may form a crosslinked bond 204 with two silicone elastomers. Sulfur may form an uncrosslinked bond 203.

### Polymer Chains

According to embodiments of the invention, the polymer coating may contain polymer chains which, after exposure to atmospheric sulfur, may be crosslinked by sulfur chains. These polymer chains may be any polymer chain capable of crosslinking through sulfur. For example, the polymer chains may be elastomers such as silicone, with sulfur crosslinks curing and hardening a silicone elastomer gel. In another example, the polymer coating may be a thermosetting plastic such as epoxy, with sulfur crosslinks hardening and reinforcing the polymer and further decreasing permeability. Traditional coating polymers that may be used include, but are not limited to, silicones, epoxies, acrylates, and urethanes. The polymer chains may also be more conventional elastomeric rubbers based on unsaturated hydrocarbons. Such elastomeric unsaturated hydrocarbon rubbers include, but are not limited to, polyisobutylene, polybutadiene, and polyisoprene. The polymer coating may be formed from a combination of monomers forming the polymer chains.

In embodiments of the invention, the polymer chains may contain unsaturated groups. These unsaturated groups include, but are not limited to, vinyl, allyl, and acrylate groups. Unsaturated groups may be part of the backbone of the polymer chain, such as polyisoprene chains. Alternatively, the unsaturated groups may be pendant to the backbone of the polymer chain, such as pendant vinyl groups on silicone. In an embodiment of the invention, a conformal coating includes silicone elastomers with unsaturated pendant groups.

The polymer coating may be formed through any known polymerization method, such as addition, condensation, and ring-opening polymerization. In an embodiment of the invention, the polymer chains are silicone elastomers with pendant unsaturated groups formed from organohalosiloxanes having unsaturated pendant groups, as seen below.

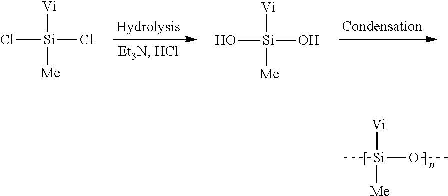

These organohalosiloxanes undergo hydrolysis and condensation reactions to form silicone elastomers having unsaturated pendant groups, such as vinyl, as shown above. The types of organohalosiloxanes may be mixed, such as dimethyl siloxane and vinyl methyl siloxane, according to the desired unsaturated group concentration of the silicone elastomers. For example, it may be desired to use a silicone gel with 5 wt. % vinyl groups. Additionally, the condensation reaction may lead to formation of cyclics, such as tetramethyl tetravinyl tetracylcosiloxane, which may undergo further base-catalyzed ring opening polymerization with siloxane terminating groups to form silicone elastomers having unsaturated pendant groups. Cyclics containing different unsaturated functional groups may be mixed to achieve the desired unsaturated group concentration. Alternatively, silicone elastomers may be formed through any intermediate discussed above, such as forming silicone elastomers through ring-opening polymerization with tetramethyl tetravinyl tetracylcosiloxane and hexamethyl disiloxane.

### Accelerators and Activators

In an embodiment of the invention, the polymer coating contains an accelerator and removes elemental sulfur through accelerated vulcanization. An accelerator may convert sulfur into a form that more readily bonds to a polymer chain. The accelerators may differ with respect to their cure time and crosslinking length and density, and may be selected based on the desired properties of the polymeric coating. The accelerator may be any accelerator capable of speeding up the vulcanization process or increasing crosslinking density or length including, but not limited to, benzothiazoles, sulfenamides, sulfenimides, guanidines, thiurams, dithiocarbamates, amines, xanthates, and dithiophosphates.

In an embodiment of the invention, the polymer coating contains an activator. An activator works with an accelerator to form an activator-accelerator complex. Activators may increase the vulcanization rate and the crosslink efficiency. The mechanism of the activator in forming the activator-accelerator complex depends on the accelerator used. Activators that may be used include, but are not limited to, zinc oxide and stearic acid.

In embodiments of the invention, accelerators and activators may be dispersed into the polymer coating. These accelerators and activators may be monodispersed or discretely dispersed. For example, it may be desired that an accelerator be present at higher concentrations near the surface of the polymer coating, where the majority of sulfur may be absorbed. Alternatively, it may be preferred that several layers of the polymer coating are applied, with different accelerator concentrations in different applications.

### Reinforcing Materials

The conformal coating's properties may be controlled through addition of other structural substances to the conformal coating. These structural substances may impart desired characteristics for the conformal coating based on its use or application. In an embodiment of the invention, the conformal coating contains a filler dispersed into the conformal coating. This filler may modify properties of the conformal coating, such as viscosity and rheology, and reinforce the conformal coating. Any structural filler may be used including, but not limited to, silica, resins, quartz, and carbon. The fillers may be bonded into the polymer coating through coupling agents if desired.

### Material Application

According the embodiments of the invention, the coating may be applied to any part of an electronic component using any known method for applying conformal coatings, including discrete coating and complete encapsulation. For example, it may be desired that only certain parts of an electronic component are covered with the polymer coating. Some discrete coating techniques that may be used include, but are not limited to, select coating, extrusion, and robotic dispensing. Alternately, it may be desired to cover the entire electronic component with the polymer coating. Some complete encapsulation techniques that may be used include, but are not limited to, dip coating, spray coating, brush coating, and flow coating. The material may be added to an application medium to apply the material to a surface. In an embodiment of the invention, the silicone material is applied in a solution contains a solvent. After the material is applied, the solvent may evaporate, leaving a silicone layer on the surface.

While embodiments have been described with respect to a resistor element, the electronic component may be any suitable component that may be subject to corrosion by a corrosive agent, including conductive members between electronic elements on a circuit board.

Although the present invention has been described in terms of specific embodiments, it is anticipated that alterations and modifications thereof will become apparent to those skilled in the art. Therefore, it is intended that the following claims be interpreted as covering all such alterations and modifications that fall within the true spirit and scope of the invention.

What is claimed is:

1. A corrosion-resistant apparatus comprising:
an electronic component containing a metal; and
a polymer coating covering the electronic component, the polymer coating comprising polymer chains with unsaturated groups capable of scavenging a corrosive agent.

2. The apparatus of claim 1, wherein the electronic component is a resistor.

3. The apparatus of claim 1, wherein the unsaturated groups are selected from the group consisting of vinyl, allyl, and acrylate.

4. The apparatus of claim 1, wherein the corrosive agent is a sulfur containing agent.

5. The apparatus of claim 1, further comprising an accelerator compound dispersed into the polymer coating.

6. The apparatus of claim 5, wherein the accelerator compound is selected from the group consisting of benzothiazoles, sulfenamides, sulfenimides, guanidines, thiurams, dithiocarbamates, amines, xanthates, and dithiophosphates.

7. The apparatus of claim 5, further comprising an activator compound.

8. The apparatus of claim 7, wherein the activator compound is zinc oxide.

9. The apparatus of claim 1, further comprising a filler.

10. The apparatus of claim 1, wherein the polymer chains comprise silicone, the unsaturated groups are unsaturated pendant groups on the polymer chains, the metal is silver, and the corrosive agent is a sulfur containing agent.

11. A method for coating an electronic device comprising:
providing an electronic component containing a metal; and
covering the electronic component with a polymer coating, the polymer coating comprising polymer chains having unsaturated groups capable of scavenging a corrosive agent.

12. The method of claim 11, wherein the electronic component is a resistor.

13. The method of claim 11, wherein the unsaturated groups are selected from the group consisting of vinyl, allyl, and acrylate.

14. The method of claim 11, wherein the polymer coating further comprises an accelerator compound dispersed into the polymer coating.

15. The method of claim 14, wherein the accelerator compound is selected from a group consisting of benzothiazoles, sulfenamides, sulfenimides, guanidines, thiurams, dithiocarbamates, amines, xanthates, and dithiophosphates.

16. The method of claim 14, wherein the polymer coating further comprises an activator compound dispersed into the polymer coating.

17. The method of claim 16, wherein the activator compound is zinc oxide.

18. The method of claim 11, further comprising exposing the polymer coating to an atmosphere containing a sulfur containing agent.

19. The method of claim 18, wherein the polymer coating is silicone, the unsaturated groups are unsaturated pendant groups on the polymer chains, the metal is silver, and the corrosive agent is a sulfur containing agent.

20. The method of claim 18, wherein the permeability of the polymer coating is decreased after being exposed to the atmosphere.
